(19) United States
(12) Patent Application Publication
(10) Pub. No.: US 2026/0328718 A1
(43) Pub. Date: Oct. 22, 2026

(54) CRACK DETECTION DEVICE, CRACK DETECTION METHOD, AND DATA DRIVING DEVICE

(71) Applicant: LX SEMICON CO., LTD., Daejeon (KR)

(72) Inventors: Sung Hae KIM, Daejeon (KR); Kyung Min SHIN, Daejeon (KR)

(73) Assignee: LX SEMICON CO., LTD., Daejeon (KR)

(21) Appl. No.: 19/104,599

(22) PCT Filed: Aug. 2, 2023
(86) PCT No.: PCT/KR2023/011352

§ 371 Date: Feb. 18, 2025

(30) Foreign Application Priority Data
Aug. 18, 2022 (KR) 10-2022-0103502
Jul. 31, 2023 (KR) 10-2023-0099387

(51) Int. Cl. G01N 27/20; G01N 27/04; G01R 31/28

(52) U.S. Cl. CPC G01N 27/20; G01N 27/045; G01R 31/2841

(57) ABSTRACT

The crack detection device may include a signal supply unit, a resistance adjustment unit, a path control unit, and a detection unit. The path control unit may select a first path and a second path. A detection signal may pass through at least one resistor through the first path. A detection signal may pass through one crack detection target among a plurality of crack detection targets through the second path. When the first path is selected, at least one resistor may be connected to the signal supply unit. When the second path is selected, a crack detection target may be connected to the signal supply unit. The detection unit may detect cracks in one crack detection target based on a first detection signal obtained from an output signal on the first path and a second detection signal obtained from an output signal on the second path.

### TECHNICAL FIELD

The embodiment relates to a crack detection device, a crack detection method, and a data driving device.

### BACKGROUND ART

As display technology advances, a flexible display, a transparent display, etc. are being developed. The flexible display may be a display that may be bent, folded, or rolled.

The flexible display is not only thin and light, but also shock-resistant. Since the flexible display has bending characteristics, it has the advantage of being able to be manufactured in various shapes. In particular, the flexible display may be used in industrial fields where application to an existing glass substrate-based display was limited or impossible.

In the flexible display, a panel, various components, and circuits are manufactured based on plastic to have bending characteristics. However, the flexible display has a problem in that defects such as cracks occur during manufacturing or use due to its bending characteristics.

### DISCLOSURE

### Technical Problem

An object of the embodiment is to solve the foregoing and other problems.

Another object of the embodiment is to provide a crack detection device, a crack detection method, and a data driving device capable of detecting defects such as cracks.

The technical problems of the embodiments are not limited to those described in this item and comprise those that may be understood through the description of the invention.

### Technical Solution

In order to achieve the above or other objects, according to the first aspect of the embodiment, a crack detection device, comprising: a signal supply unit configured to supply a detection signal; a resistance adjustment unit configured to adjust a reference resistance value to correspond to resistance values of a plurality of crack detection targets using a plurality of resistors; a path control unit configured to select a first path and a second path, and in which the detection signal passes through at least one resistor through the first path and passes through one of the plurality of crack detection targets through the second path; and a detection unit configured to detect cracks in the one crack detection target based on a first detection signal obtained from an output signal on the first path and a second detection signal obtained from an output signal on the second path, wherein when the first path is selected, the at least one resistor is connected to the signal supply unit, and when the second path is selected, the crack detection target is connected to the signal supply unit.

One period may comprise a first section and a second section. In this instance, the detection unit may obtain the first detection signal during the first section, and obtain the second detection signal during the second section.

The plurality of resistors may be connected in parallel with each other. In this instance, the resistance adjustment unit may comprise a plurality of first switches configured to be connected in series to the plurality of resistors, respectively.

The resistance adjustment unit may adjust the reference resistance value to correspond to a resistance value of the one crack detection target by switching the plurality of first switches.

The resistance adjustment unit may comprise a second switch connected in parallel with the resistor.

The path control unit may select a third path through which the detection signal passes through the second switch. The detection unit may detect cracks in the one crack detection target based on the first detection signal, the second detection signal, and the third detection signal. The third detection signal may be obtained on the selected third path.

The one period may comprise a third section. In this instance, the detection unit may obtain the third detection signal during the third section.

According to the second aspect of the embodiment to achieve the above or other objects, a crack detection method, comprising: supplying, by a signal supply unit, a detection signal; adjusting, by a resistance adjustment unit, a reference resistance value to correspond to resistance values of a plurality of crack detection targets using a plurality of resistors; selecting, by a path control unit, a first path and a second path—wherein the detection signal passes through at least one resistor through the first path and passes through one crack detection target among the plurality of crack detection targets through the second path; and detecting, by a detection unit, cracks in the one crack detection target based on a first detection signal obtained from an output signal on the first path and a second detection signal obtained from an output signal on the second path, wherein when the first path is selected, the at least one resistor is configured to be connected to the signal supply unit, and when the second path is selected, the crack detection target is configured to be connected to the signal supply unit.

The crack detection method may comprise: selecting a third path through which the detection signal passes through a second switch connected in parallel with the resistor. In this instance, the detecting of cracks may comprise: detecting cracks in the one crack detection target based on the first detection signal, the second detection signal, and the third detection signal. The third detection signal may be obtained on the selected third path.

According to the third aspect of the embodiment to achieve the above or other objects, a data driving device configured to supply a data signal to a panel, comprising: a plurality of source driving circuits, each of which comprises a crack detection device, wherein the crack detection device comprises: a signal supply unit configured to supply a detection signal; a first resistance adjustment unit configured to adjust a reference resistance value to correspond to resistance values of a plurality of crack detection targets using a plurality of first resistors; a path control unit configured to select a first path and a second path, and in which the detection signal passes through at least one resistor through the first path and passes through one of the plurality of crack detection targets through the second path; and a detection unit configured to detect cracks in the one crack detection target based on a first detection signal obtained from an output signal on the first path and a second detection signal obtained from an output signal on the second path, wherein when the first path is selected, the at least one resistor is connected to the signal supply unit, and when the second path is selected, the crack detection target is connected to the signal supply unit.

One of the plurality of source driving circuits may be designated as a master source driving circuit, and the remaining source driving circuits may be designated as slave source driving circuits. In this instance, in the master source driving circuit, the detection unit may obtain the first detection signal from the panel as the one crack detection target by passing the detection signal through the panel and the plurality of slave source driving circuits.

In the master source driving circuit, the crack detection device may comprises: a second resistance adjustment unit configured to offset resistance values of the plurality of slave source driving circuits using a plurality of second resistors.

One of the plurality of source driving circuits may be designated as a master source driving circuit, and the remaining source driving circuits may be designated as slave source driving circuits. In this instance, in the master source driving circuit, the detection unit may obtain the first detection signal from the master source driving circuit as the one crack detection target by passing detection signal through the master source driving circuit.

One of the plurality of source driving circuits may be designated as a master source driving circuit, and the remaining source driving circuits may be designated as slave source driving circuits. In this instance, in one of the designated plurality of slave source driving circuits, the detection unit may obtain the first detection signal from the one slave source driving circuit as the one crack detection target by passing the detection unit through the one slave source driving circuit.

The plurality of first resistors may be connected in parallel with each other. The first resistance adjustment unit may comprise a plurality of first switches, each of which is connected in series to the plurality of first resistors.

The first resistance adjustment unit may adjust the reference resistance value to correspond to a resistance value of the one crack detection target by switching the plurality of first switches.

The first resistance adjustment unit may comprise a second switch connected in parallel with the first resistor.

The path control unit may select a third path through which the detection signal passes through the second switch. The detection unit may detect cracks in the one crack detection target based on the first detection signal, the second detection signal, and the third detection signal. The third detection signal may be obtained on the selected third path.

### Advantageous Effects

The effects of the crack detection device, the crack detection method, and the data driving device according to the embodiments are described as follows.

According to at least one of the embodiments, cracks may be accurately and quickly detected for each of a plurality of crack detection targets.

According to at least one of the embodiments, cracks may be detected by considering the resistance value existing in a signal supply unit, a multiplexer, a detection unit, etc., so that the accuracy of the crack detection can be dramatically increased.

According to at least one of the embodiments, the internal resistance value of each of the switches for connecting a plurality of slave source driving circuits reflected in a second detection signal obtained on a second path through a panel is offset by the internal resistance value of a plurality of third switches of ta second resistance adjustment unit reflected in a first detection signal obtained on a first path, so that errors in the crack detection for the panel can be prevented.

### DESCRIPTION OF DRAWINGS

FIG. 1 is a block diagram of a display device according to a first embodiment.

FIG. 2 illustrates a crack detection device according to the first embodiment.

FIG. 3 illustrates the detection unit of FIG. 2.

FIG. 4 is a circuit diagram of a resistance adjustment unit according to the first embodiment.

FIG. 5 is an operation waveform diagram of a crack detection device according to the first embodiment.

FIG. 6A is an operation waveform diagram for detecting a first crack detection target in the detection unit of FIG. 2.

FIG. 6B is an operation waveform diagram for detecting a second crack detection target in the detection unit of FIG. 2.

FIG. 7 illustrates a state in which a path control unit operates to obtain a first detection signal on a first path.

FIG. 8 illustrates a state in which a path control unit operates to obtain a second detection signal on a second path.

FIG. 9 illustrates a detection pad provided on a panel.

FIG. 10 is a circuit diagram of a resistance adjustment unit according to a second embodiment.

FIG. 11 is another operation waveform diagram of a crack detection device according to the first embodiment.

FIG. 12 illustrates a state in which a path control unit operates to obtain a third detection signal on a third path.

FIG. 13 is a block diagram of a display device according to the second embodiment.

FIG. 14 illustrates a crack detection device according to the second embodiment.

FIG. 15 is a circuit diagram of the first resistance adjustment unit and the second resistance adjustment unit of FIG. 14.

FIG. 16 illustrates a crack detection device according to the second embodiment detecting cracks on a panel.

FIG. 17 illustrates a state in which a detection signal passes through the first resistance adjustment unit and the second resistance adjustment unit when detecting cracks on a panel.

The sizes, shapes, dimensions, etc. of elements illustrated in the drawings may differ from actual ones. In addition, even if the same elements are illustrated in different sizes, shapes, dimensions, etc. between the drawings, this is only an example on the drawing, and the same elements have the same sizes, shapes, dimensions, etc. between the drawings.

### MODE FOR INVENTION

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, region or substrate is referred to as being ‘on’ another element, this means that there may be directly on the other element or be other intermediate elements therebetween.

Hereinafter, “~module”, “unit”, etc. may be configured as “~circuit”. “Module”, “unit”, etc. may be configured as an integrated circuit. In the following, the drawing reference numerals missing in the corresponding drawings may be replaced with the drawing reference numerals of components having the same function or mathematical value in other drawings.

### Display Device According to a First Embodiment

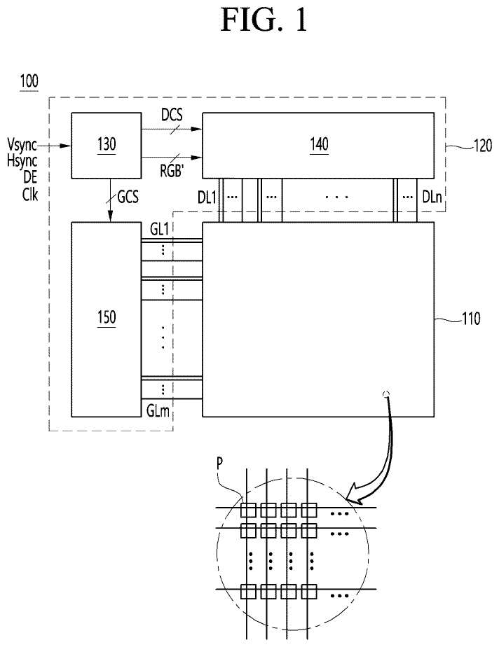

FIG. 1 is a block diagram of a display device according to a first embodiment.

Referring to FIG. 1, the display device 100 according to the embodiment may comprise a panel 110 and a display driving device 120.

The display device 100 may comprise a flexible display device having a bending characteristic. The embodiment may also be applied to a rigid display device without a bending characteristic. Examples of the flexible display device 100 comprise an organic light-emitting element (OLED) display device 100, a liquid crystal display device 100, a field emission display device 100, an electrophoretic display device 100, etc.

The panel 110 may comprise a plurality of gate lines GL1 to GLm, a plurality of data lines DL1 to DLn, and a plurality of pixels P. The plurality of pixels P may be connected to the plurality of gate lines GL1 to GLm and the plurality of data lines DL1 to DLn.

The panel 110 may receive a data signal in units of frames and display an image corresponding to the data signal.

Meanwhile, the display driving device 120 may provide a data signal to the panel 110 in units of frames and display an image on the panel 110. The display driving device 120 may comprise a data processing device 130, a gate driving device 150, and a data driving device 140.

At least one or more of the data processing device 130, the gate driving device 150, and the data driving device 140 may be configured as an integrated circuit. The data processing device 130 may comprise a timing controller. The data processing device 130 may be called a processor, a microprocessor, a microcontroller unit (MCU), a control device, a control circuit, a control IC, etc.

The data processing device 130 may generate control signals GCS and DCS for driving the gate driving device 150 and the data driving device 140 by using various timing signals comprising a vertical synchronization signal Vsync, a horizontal synchronization signal Hsync, a data enable DE signal, a clock signal CLK, etc. from an external system (not shown).

The gate driving device 150 may shift a scan pulse based on a gate control signal GCS provided from the data processing device 130 and sequentially supply the scan pulse to the gate lines GL1 to GLm.

Meanwhile, the data driving device 140 may convert digital data RGB′ into an analog data signal according to a data control signal DCS from the data processing device 130 and provide it to the panel 110 for each line.

Meanwhile, in the display device 100 according to the embodiment, the panel 110 or the display driving device 120 has a bending characteristic for a flexible display, so that there is a problem that cracks occur during manufacturing or product use.

Hereinafter, various embodiments that may detect defects such as cracks will be described.

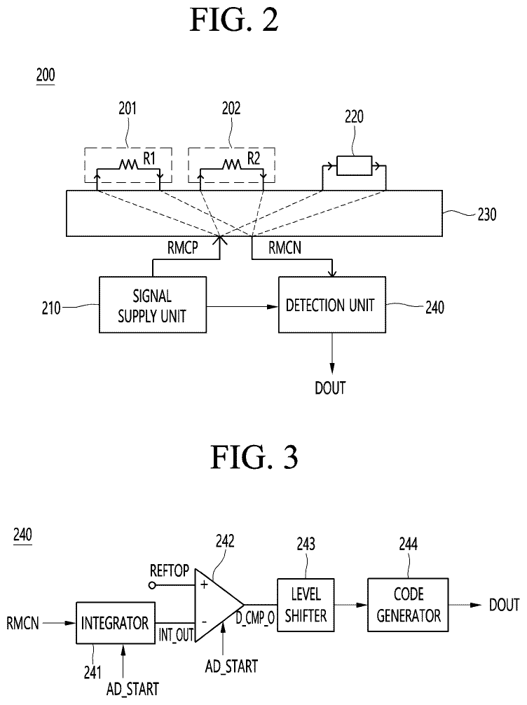

FIG. 2 illustrates a crack detection device according to the first embodiment. FIG. 3 illustrates a detection unit of FIG. 2.

Referring to FIGS. 2 and 3, the crack detection device 200 according to the first embodiment may comprise a signal supply unit 210, a resistance adjustment unit 220, a path control unit 230, and a detection unit 240.

The signal supply unit 210 may supply a detection signal RMCP. The detection signal RMCP may be a DC voltage having a high level, but is not limited thereto. The signal supply unit 210 may adjust the high level of the DC voltage. The detection signal RMCP may be supplied to the path control unit 230. The signal supply unit 210 may supply a reference signal REFTOP. The reference signal REFTOP may be supplied to a comparator 242 of the detection unit 240.

The resistance adjustment unit 220 may adjust the resistance values Rref11 to Rref1k to correspond to the resistance values R1 and R2 of the plurality of crack detection targets 201 and 202, respectively. The crack detection targets 201 and 202 may mean targets for which crack detection is to be performed. The panel 110 or the driving devices illustrated in FIG. 1 may be the crack detection targets 201 and 202. For example, the data processing device 130, the data driving device 140, the gate driving device 150, etc. may be the crack detection targets 201 and 202. When the data driving device 140 comprises a plurality of source driving circuits 140-1 to 140-L, each of the plurality of source driving circuits 140-1 to 140-L may be the crack detection targets 201 and 202.

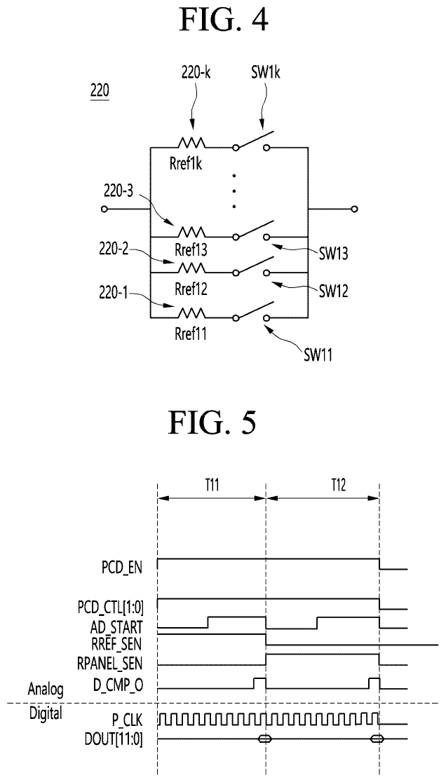

The resistance adjustment unit 220 may comprise a plurality of resistors 220-1 to 220-k, as illustrated in FIG. 4. The plurality of resistors 220-1 to 220-k may be connected in parallel with each other. The plurality of resistors 220-1 to 220-k may have a plurality of resistance values Rref11 to Rref1k that are different from each other, respectively. For example, the resistance value Rref11 of the first resistor 220-1 may be the smallest, and the resistance value Rref1k of the Kth resistor 220-k may be the largest.

The resistance adjustment unit 220 may comprise a plurality of switches SW11 to SW1k. The plurality of switches SW11 to SW1k may be connected in series to the plurality of resistors 220-1 to 220-k, respectively.

The resistance adjustment unit 220 may adjust the reference resistance value to correspond to the resistance values R1 and R2 of the plurality of crack detection targets 201 and 202, respectively, by switching the plurality of switches SW11 to SW1k.

As an example, the resistance values R1 and R2 of the plurality of crack detection targets 201 and 202 may be the same as the resistance values Rref11 to Rref1k of the plurality of resistors 220-1 to 220-k, respectively. For example, the resistance value Rref1k of the resistor 220-k may be the same as the resistance value R1 of the first crack detection target 201. In this instance, when crack detection is performed for the first crack detection target 201, the resistance adjustment unit 220 may turn on the switch SW1k to adjust the reference resistance value using the resistance value Rref1K of the resistor 220-k. For example, the resistance value Rref12 of the resistor 220-2 may be the same as the resistance value of the second crack detection target 202. In this instance, when crack detection is performed on the second crack detection target 202, the resistance adjustment unit 220 may turn on the switch SW12 to adjust the resistance value Rref12 of the resistor 220-2 to a reference resistance value. Accordingly, when the resistance values R1 and R2 of the plurality of crack detection targets 201 and 202 are equal to the resistance values Rref11 to Rref1k of the plurality of resistors 220-1 to 220-k, respectively, the resistance adjustment unit 220 may switch one switch when cracks are detected.

As another example, the resistance values R1 and R2 of the plurality of crack detection targets 201 and 202 may be different from the resistance values Rref11 to Rref1k of the plurality of resistors 220-1 to 220-k, respectively. For example, the resistance value R1 of the first crack detection target 201 may be equal to the total resistance value of the resistance value Rref1 (k-1) of the resistor 220-(k-1) and the resistance value Rref1k of the resistor 220-k. In this instance, when crack detection is performed on the first crack detection target 201, the resistance adjustment unit 220 may turn on the switches SW1(k-1)) and SW1k to make the reference resistance value equal to the resistance value R1 of the first crack detection target 201. Accordingly, when the resistance values R1 and R2 of the plurality of crack detection targets 201 and 202 are different from the resistance values Rref11 to Rref1k of the plurality of resistors 220-1 to 220-k, respectively, the resistance adjustment unit 220 may switch at least one or more switch when detecting cracks.

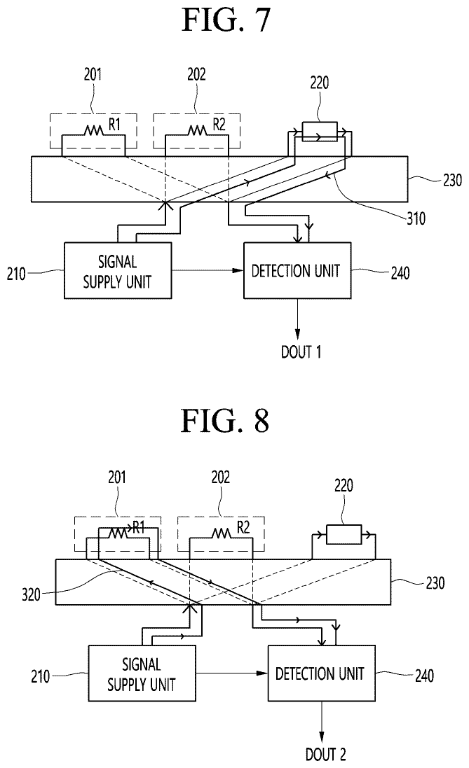

Meanwhile, the path control unit 230 may select a plurality of paths (310 of FIGS. 7 and 320 of FIG. 8). For example, the path control unit 230 may comprise a multiplexer, but is not limited thereto. The path may comprise a first path 310 and a second path 320. The first path 310 may be a path for obtaining a first detection signal DOUT1 using a reference resistance value adjusted by a resistance adjustment unit 220. The second path 320 may be a path for obtaining a second detection signal DOUT2 using a resistance value of one crack detection target among a plurality of crack detection targets 201 and 202. Since the second detection signal DOUT2 may be obtained for each of the plurality of crack detection targets 201 and 202, the second path 320 may be configured in plural.

The path control unit 230 may select the first path 310 to obtain the first detection signal DOUT1 using the first path 310 for each of a plurality of crack detection targets 201 and 202, or select the second path 320 to obtain the second detection signal DOUT2 using the second path 320. The path control unit 230 may select the first path 310 so that resistance adjustment unit 220 is connected to the signal supply unit 210 and the detection unit 240. The path control unit 230 may select the second path 320 so that plurality of crack detection targets 201 and 202 are connected to the signal supply unit 210 and the detection unit 240.

When the first path 310 is selected, the detection unit 240 may obtain the first detection signal DOUT1 on the first path 310 (FIG. 7). When the first path 310 is selected, the first detection signal DOUT1 may be obtained by the detection signal RMCP passing through at least one resistor 220-1 to 220-k used to adjust the reference resistance value. When the second path 320 is selected, the detection unit 240 may obtain the second detection signal DOUT2 on the second path 320 (FIG. 8). When the second path 320 is selected, the second detection signal DOUT2 may be obtained by the detection signal RMCP passing through one of the plurality of crack detection targets 201 and 202.

Meanwhile, the detection unit 240 may detect cracks in each of the plurality of crack detection targets 201 and 202 based on the first detection signal DOUT1 obtained on the first path 310 and the second detection signal DOUT2 obtained on the second path 320.

For example, a first output signal RMCN through the resistance adjustment unit 220 on the first path 310 may be provided to the detection unit 240. The detection unit 240 may obtain the first detection signal DOUT1 by performing computational processing on the first output signal RMCN. For example, a first output signal RMCN through a specific crack detection target 201 and 202 on the second path 320 may be provided to the detection unit 240. The detection unit 240 may obtain the second detection signal DOUT2 by performing computational processing on the first output signal RMCN. The detection unit 240 may detect cracks in a specific crack detection target 201 and 202 based on the first detection signal DOUT1 and the second detection signal DOUT2. The first detection signal DOUT1 and the second detection signal DOUT2 may each have a code value composed of a binary number.

Referring to FIG. 3, the detection unit 240 may comprise an integrator 241, a comparator 242, and a code generator 244.

The integrator 241 may perform an integral calculation on the first output signal RMCN output on the first path 310 or the second path 320 and output the second output signal INT_OUT. The second output signal INT_OUT may have a slope that increases over time because it performs an integral operation on the first output signal RMCN. The slope may vary depending on the resistance values R1 and R2 of the plurality of crack detection targets 201 and 202, respectively, or the reference resistance value adjusted by the resistance adjustment unit 220. For example, the slope may decrease as the resistance values R1 and R2 increase.

The comparator 242 may compare the second output signal INT_OUT with the reference signal REFTOP and output a third output signal D_CMP_O. The reference signal REFTOP may be generated by the signal supply unit 210, but is not limited thereto. The reference signal REFTOP may be constant regardless of the resistance values R1 and R2 of the plurality of crack detection targets 201 and 202, respectively, but is not limited thereto. However, as described above, the slope of the second output signal INT_OUT may be different depending on the resistance values R1 and R2 of the plurality of crack detection targets 201 and 202, respectively.

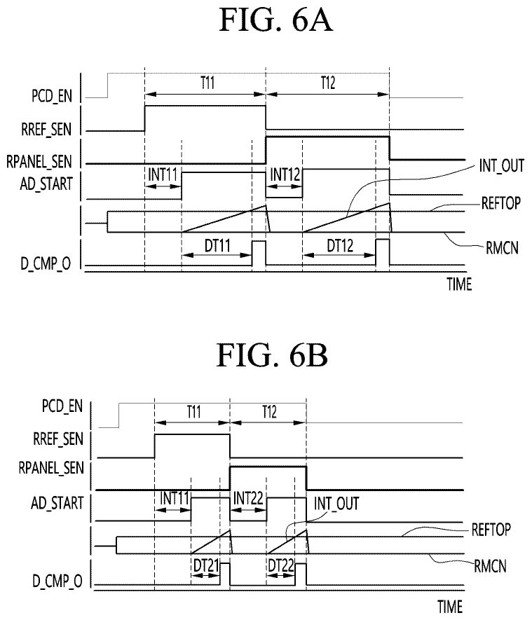

In this instance, the point in time at which the second output signal INT_OUT meets the reference signal REFTOP when detecting cracks of each of the plurality of crack detection targets 201 and 202 may be different. For example, the smaller the resistance values R1 and R2 of the plurality of crack detection targets 201 and 202, respectively, the greater the slope of the second output signal INT_OUT, so that the point in time at which the second output signal INT_OUT meets the reference signal REFTOP may be shortened. Accordingly, the operation sections of the integrator 241 and the comparator 242 may be different depending on the resistance values R1 and R2 of the plurality of crack detection targets 201 and 202, respectively. Each operation section of the integrator 241 and the comparator 242 may be determined by a control signal AD_START (FIG. 5, FIG. 6A and FIG. 6B).

For example, a starting time of each operation section of the integrator 241 and the comparator 242 may be the same regardless of the respective resistance values R1 and R2 of the plurality of crack detection targets 201 and 202. However, an end time of each operation section of the integrator 241 and the comparator 242 may vary depending on the respective resistance values R1 and R2 of the plurality of crack detection targets 201 and 202. As the respective resistance values R1 and R2 of the plurality of crack detection targets 201 and 202 increase, the end time of each operation section of the integrator 241 and the comparator 242 may move further away from the starting time.

Meanwhile, the third output signal D_CMP_O may comprise a pulse signal. A rising time of the pulse signal may be a time at which the second output signal INT_OUT meets the reference signal REFTOP. A falling time of the pulse signal may coincide with an end time of each operation section of the integrator 241 and the comparator 242.

Meanwhile, the detection unit 240 may comprise a level shifter 243. The level shifter 243 may be connected between the comparator 242 and the code generator 244. The third output signal D_CMP_O of the comparator 242 may be provided to the level shifter 243. The level shifter 243 may output a fourth output signal that is lower than the level of the third output signal D_CMP_O. The fourth output signal may be provided to the code generator 244. The level shifter 243 may be an analog-to-digital converter that converts an analog signal into a DC signal, but is not limited thereto. The code generator 244 may generate a code value using the fourth output signal converted into a digital signal by the level shifter 243. Accordingly, a code value may be generated by counting using a frequency modulated through a clock dividing option in a digital counter instead of an analog counter, so that overflow can be prevented. In the case of clock division, operation is possible up to a speed where the driving speed of 154 MHz is divided by 2, 4, and 8. Overflow may mean an error in which when the second output signal INT_OUT does not meet the reference signal REFTOP within a set time section, the third output signal D_CMP_O is not generated, so that counting is not completed, and a detection signal is not obtained. However, according to the embodiment, since the code generator 244 counts using a frequency modulated through a clock dividing option in a digital counter, the desired counting may be performed within a set time section, so that overflow can be prevented and the accuracy of crack detection that enables the generation of precise code values can be increased.

When the code generator 244 counts using an analog counter, the level shifter 243 may be omitted. That is, the third output signal D_CMP_O output from the comparator 242 may be provided to the code generator 244 without passing through the level shifter 243.

Referring again to FIG. 3, the code generator 244 may generate a code value based on the third output signal D_CMP_O or the fourth output signal.

For example, the code value may be generated by counting the rising time of the third output signal D_CMP_O or the fourth output signal. The number of counting times may increase as the rising time of the third output signal D_CMP_O or the fourth output signal becomes later in time. A larger code value may be generated as the number of counting times increases, but is not limited thereto.

For example, the code value may be generated based on the number of counting times counted during a predetermined detection section (DT11 and DT12 of FIG. 6A and DT21 and DT22 of FIG. 6B). The detection section DT11, DT12, DT21 and DT22) may be a section between the rising time of the control signal AD_START and the rising time of the third output signal D_CMP_O or the fourth output signal.

The code value may constitute a detection signal DOUT, but is not limited thereto. In other words, the detection signal DOUT may comprise the code value. Accordingly, the code generator 244 may generate a detection signal DOUT comprising different code values according to the resistance values R1 and R2 of the plurality of crack detection targets 201 and 202, respectively, or the reference resistance value adjusted by the resistance adjustment unit 220.

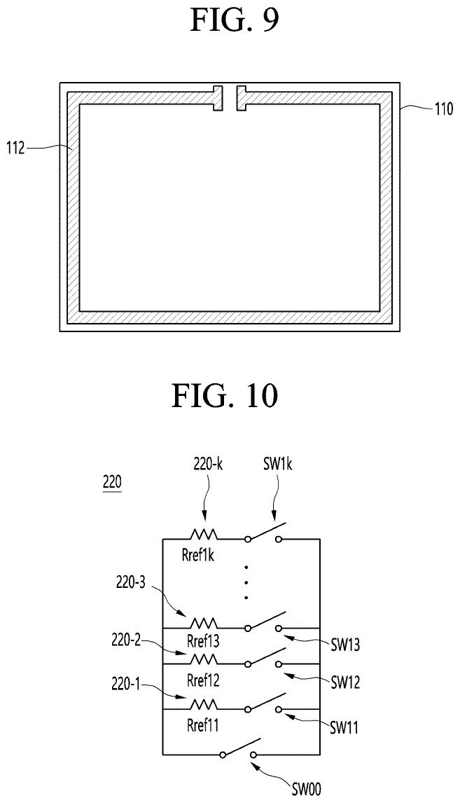

Meanwhile, as illustrated in FIG. 9, a detection pad 112 may be provided on the panel 110. The detection pad 112 may be formed of a conductive material. For example, the detection pad 112 may be made of a metal or a conductive oxide film, such as ITO, but is not limited thereto. The detection pad 112 may have a predetermined resistance value. The resistance value of the detection pad 112 may be the resistance value R1 of the panel 110 as the crack detection target 201 and 202. Accordingly, the resistance value R1 of the panel 110 and the resistance value of the detection pad 112 may be mixed.

For example, when the second detection signal DOUT2 is obtained via the detection pad 112 of the panel 110, the second detection signal DOUT2 may comprise a code value corresponding to the resistance value R1 of the detection pad 112 provided on the panel 110. When detecting cracks in the panel 110, the resistance adjustment unit 220 may adjust the reference resistance value to the resistance value R1 of the detection pad 112 provided on the panel 110. In this instance, when the first detection signal DOUT1 is obtained via the resistance adjustment unit 220, the first detection signal DOUT1 may comprise a code value corresponding to the adjusted reference resistance value.

### Operation Method of Crack Detection

The operation method of crack detection is explained below with reference to FIGS. 5 to 8. The drawing reference numerals omitted in the description of FIGS. 5 to 8 may be adopted in FIGS. 1 to 4. FIGS. 5 to 8 illustrate the operation method of crack detection for the first crack detection target, but the operation method of crack detection for other crack detection targets may also be easily understood from the drawings illustrated in FIGS. 5 to 8.

FIG. 5 is an operation waveform diagram of a crack detection device according to the first embodiment. FIG. 6A is an operation waveform diagram for detecting the first crack detection target in the detection unit of FIG. 2. FIG. 7 illustrates a state in which a path control unit operates to obtain a first detection signal on a first path. FIG. 8 illustrates a state in which a path control unit operates to obtain a second detection signal on a second path.

In the embodiment, the detection signal DOUT for the crack detection target 201 and 202 may be obtained for one period. The enable signal PCD_EN may control the periodic operation of the crack detection device 200 according to the embodiment. The crack detection device 200 according to the embodiment may operate for each period in response to the high level of the enable signal PCD_EN to obtain the detection signal DOUT for the crack detection target 201 and 202.

One period may comprise a first section T11 and a second section T12. In this instance, the first detection signal DOUT1 may be obtained for the first section T11, and the second detection signal DOUT2 may be obtained for the second section T12. The first detection signal DOUT1 may be obtained on the first path 310, and the second detection signal DOUT2 may be obtained on the second path 320. To this end, the path control unit 230 may select the first path 310 or the second path 320.

The path control unit 230 may receive a control signal PCD_CTL, a first enable signal RREF_SEN, and a second enable signal RPANEL_SEN. The control signal PCD_CTL may be a signal that controls selection of each of a plurality of crack detection targets 201 and 202. The width of the high level of the control signal PCD_CTL may be the same as the width of the high level of the enable signal PCD_EN, but is not limited thereto. The first enable signal RREF_SEN may be a signal for controlling selection of a first path 310 passing through a resistance adjustment unit 220 whose reference resistance value is adjusted to the resistance values R1 and R2 of the selected crack detection target 201 and 202. The second enable signal RPANEL_SEN may be a signal for controlling selection of a second path 320 passing through the selected crack detection target 201 and 202.

The control signal PCD_CTL and the first enable signal RREF_SEN may be provided to the path control unit 230 at the same time, and the second enable signal RPANEL_SEN may be provided to the path control unit 230 at a later time than the first enable signal RREF_SEN, but is not limited thereto. The control signal PCD_CTL may coincide with one period, but is not limited thereto. The first enable signal RREF_SEN may coincide with the first section T11 of one period, and the second enable signal RPANEL_SEN may coincide with the second section T12 of one period, but is not limited thereto. The rising time of the control signal PCD_CTL and the rising time of the first enable signal RREF_SEN may be the same, and the falling time of the control signal PCD_CTL and the falling time of the second enable signal RPANEL_SEN may be the same. The rising time of the second enable signal RPANEL_SEN may be the same as or later than the falling time of the first enable signal RREF_SEN.

### Operation in a First Section T11

As illustrated in FIG. 7, the path control unit 230 may select the first path 310 to connect the resistance adjustment unit 220 with the signal supply unit 210 and the detection unit 240 during the first section T11.

First, the path control unit 230 may perform path control of the first crack detection target 201 in response to the control signal PCD_CTL.

The path control unit 230 may select the first path 310 in response to the first enable signal RREF_SEN, so that the resistance adjustment unit 220 may be connected to the signal supply unit 210 and the detection unit 240. At this time, the reference resistance value in the resistance adjustment unit 220 may be adjusted to the resistance value R1 of the first crack detection target 201. The detection signal RMCP of the signal supply unit 210 may be output to the detection unit 240 via the path control unit 230 and the resistance adjustment unit 220. Accordingly, the first output signal RMCN generated by the detection signal RMCP via the resistance adjustment unit 220 may be output to the detection unit 240. The first output signal RMCN may be voltage or current.

The detection unit 240 may obtain the first detection signal DOUT1 based on the first output signal RMCN. Specifically, as illustrated in FIG. 3, FIG. 5, and FIG. 6A, the integrator 241 and the comparator 242 may operate in response to the control signal AD_START.

The rising time of the control signal AD_START may be later than the rising time of the first enable signal RREF_SEN or the second enable signal RPANEL_SEN. That is, the section between the rising time of the first enable signal RREF_SEN or the second enable signal RPANEL_SEN and the rising time of the control signal AD_START may be defined as an initialization section (INT11 and INT12 of FIG. 6A and INT21 and INT22 of FIG. 6B). For example, the integrator 241 or the comparator 242 may be initialized during the initialization sections INT11, INT12, INT21 and INT22, but is not limited thereto. The initialization section may be omitted. That is, the rising time of the control signal AD_START may coincide with the rising time of the first enable signal RREF_SEN or the second enable signal RPANEL_SEN.

The integrator 241 may perform an integral operation on the first output signal RMCN in response to the control signal AD_START to generate a second output signal INT_OUT that increases over time. The generated second output signal INT_OUT may be provided to the comparator 242.

The comparator 242 may compare the second output signal INT_OUT with the reference signal REFTOP to generate a third output signal D_CMP_O. The reference signal REFTOP has a constant high level and the second output signal INT_OUT increases over time, so that the second output signal INT_OUT may meet the high level of the reference signal REFTOP.

The point in time when the second output signal INT_OUT meets the high level of the reference signal REFTOP may coincide with a rising time of the third output signal D_CMP_O. That is, the pulse of the third output signal D_CMP_O may be generated at the point in time when the second output signal INT_OUT meets the high level of the reference signal REFTOP. Meanwhile, the falling time of the third output signal D_CMP_O may be synchronized with the falling time of the control signal AD_START provided to the comparator 242 and the integrator 241. Therefore, the third output signal D_CMP_O may be provided to the code generator 244 via the level shifter 243 as a pulse signal.

The code generator 244 may count using a clock signal P_CLK based on the starting time, i.e., the rising time, of the control signal AD_START provided to the comparator 242 and the integrator 241. The code generator 244 may end the counting in synchronization with the rising time of the third output signal D_CMP_O. Accordingly, the code generator 244 may generate the first detection signal DOUT1 comprising the code value based on the number of times counted during a section between the rising time of the control signal AD_START and the rising time of the third output signal D_CMP_O. The first detection signal DOUT1 may be a signal in which the reference resistance value adjusted by the resistance adjustment unit 220 is reflected. The reference resistance value adjusted in the resistance adjustment unit 220 may be the same as the resistance value R1 of the first crack detection target 201.

### Operation in a Second Section T12

As illustrated in FIG. 8, the path control unit 230 may select the second path 320 to connect the first crack detection target 201 to the signal supply unit 210 and the detection unit 240 during the second section T12.

The path control unit 230 may select the second path 320 in response to the second enable signal RPANEL_SEN, so that the first crack detection target 201 may be connected to the signal supply unit 210 and the detection unit 240. The detection signal RMCP of the signal supply unit 210 may be output to the detection unit 240 via the path control unit 230 and the first crack detection target 201. Accordingly, the first output signal RMCN generated by the detection signal RMCP via the first crack detection target 201 may be output to the detection unit 240. The first output signal RMCN may be voltage or current.

The detection unit 240 may obtain the second detection signal DOUT2 based on the first output signal RMCN.

Specifically, as illustrated in FIG. 3, FIG. 5, and FIG. 6A, the integrator 241 and the comparator 242 may operate in response to the control signal AD_START. The integrator 241 may generate a second output signal INT_OUT that increases over time by performing an integral operation on the first output signal RMCN in response to the control signal AD_START. The generated second output signal INT_OUT may be provided to the comparator 242.

The comparator 242 may compare the second output signal INT_OUT with the reference signal REFTOP to generate the third output signal D_CMP_O. The reference signal REFTOP has a constant high level, and the second output signal INT_OUT increases over time, so that the second output signal INT_OUT may meet the high level of the reference signal REFTOP.

The point in time when the second output signal INT_OUT meets the high level of the reference signal REFTOP may coincide with the rising time of the third output signal D_CMP_O. That is, the pulse of the third output signal D_CMP_O may be generated at the point in time where the second output signal INT_OUT meets the high level of the reference signal REFTOP. Meanwhile, the falling time of the third output signal D_CMP_O may be synchronized with the falling time of the control signal AD_START provided to the comparator 242 and the integrator 241.

Therefore, the third output signal D_CMP_O may be provided to the code generator 244 as a pulse signal via the level shifter 243.

The code generator 244 may count using the clock signal P_CLK based on the starting time, i.e., the rising time, of the control signal AD_START provided to the comparator 242 and the integrator 241. The code generator 244 may end counting in synchronization with the rising time of the third output signal D_CMP_O. Therefore, the code generator 244 may generate a second detection signal DOUT2 comprising a code value based on the number of times counted during the section between the rising time of the control signal AD_START and the rising time of the third output signal D_CMP_O. The second detection signal DOUT2 may be a signal in which the resistance value R1 of the first crack detection target 201 is reflected.

The crack detection device 200 according to the embodiment may detect cracks for the first crack detection target 201 based on the first detection signal DOUT1 and the second detection signal DOUT2.

That is, cracks for the first crack detection target 201 may be detected using the following mathematical formula 1. Mathematical formula 1 may be an estimated resistance value obtained by the crack detection device 200 according to the first embodiment for the first crack detection target 201, i.e., the panel 110, but estimated resistance values for other crack detection targets 201 and 202 may also be obtained using mathematical formula 1.

RPANEL=Rref·(TPANEL[code]/TREF[code]) [Mathematical Formula 1]

RPANEL is an estimated resistance value for the panel 110 obtained by the crack detection device 200 according to the embodiment, and Rref may be a reference resistance value adjusted by the resistance adjustment unit 220. TREF[code] may be a code value of a first detection signal DOUT1 obtained on a first path 310 via a resistance adjustment unit 220, and TPANEL[code] may be a code value of a second detection signal DOUT2 obtained on a second path 320 via a first crack detection target 201.

RPANEL, Rref. TREF[code] and TPANEL[code] may have binary values, but are not limited thereto.

When the reference resistance value is adjusted to the same resistance value as the actual resistance value of the first crack detection target 201 in the resistance adjustment unit 220 using mathematical formula 1, the code value of the first detection signal DOUT1 obtained on the first path 310 and the code value of the second detection signal DOUT2 obtained on the second path 320 may be the same. In this instance, the estimated resistance value for the panel 110 may be the same as the reference resistance value adjusted by the resistance adjustment unit 220.

The crack detection device 200 according to the embodiment may detect cracks by comparing the estimated resistance value for the panel 110 with the actual resistance value for the panel 110. When the estimated resistance value for the panel 110 and the actual resistance value for the panel 110 are the same, the cracks are not detected and the first crack detection target 201 may be determined as a good product. When the estimated resistance value for the panel 110 and the actual resistance value for the panel 110 are different, the cracks may be detected and the first crack detection target 201 may be determined as a defective product. The actual resistance value for the panel 110 may be a resistance value measured for the detection pad 112 provided at the edge of the panel 110 as illustrated in FIG. 9, but is not limited thereto. The detection pad 112 illustrated in FIG. 9 is only an example and may be modified into various shapes or structures.

Meanwhile, even if the estimated resistance value for the panel 110 and the actual resistance value for the panel 110 are different, when the difference is within a certain range, the first crack detection target 201 may be determined as a good product.

Meanwhile, as illustrated in FIGS. 5, 6A, 7, and 8, the crack detection operation for the second crack detection target 202 may also be the same as the crack detection operation for the first crack detection target 201 described above, and therefore, a detailed description thereof will be omitted.

As illustrated in FIGS. 6A and 6B, when performing crack detection on each of the first crack detection target 201 and the second crack detection target 202, the reference signal REFTOP input to the comparator 242 may be the same. Since the resistance value R2 of the second crack detection target 202 is smaller than the resistance value R1 of the first crack detection target 201, the slope of the second output signal INT_OUT generated from the second crack detection target 202 may be larger than the slope of the second output signal INT_OUT generated from the first crack detection target 201. Accordingly, since the rising time of the third output signal D_CMP_O generated from the second crack detection target 202 is earlier than the rising time of the third output signal D_CMP_O generated from the first crack detection target 201, a code value may be obtained with a smaller number of counting times. Accordingly, different code values may be obtained according to the resistance values R1 and R2 of the plurality of crack detection targets 201 and 202, respectively, and the detection signal DOUT comprising these code values may also be different.

As described above, the first detection signal DOUT1 may comprise a code value reflecting the reference resistance value adjusted by the resistance adjustment unit 220, and the second detection signal DOUT2 may comprise a code value reflecting the resistance value R1 of the first crack detection target 201.

Meanwhile, various resistance values may exist on the first path 310 where the first detection signal DOUT1 is obtained or the second path 320 where the second detection signal DOUT2 is obtained. For example, various resistance values may exist in the signal supply unit 210, the path control unit 230, and the detection unit 240. In addition, resistance values may exist in the integrator 241, the comparator 242, the level shifter 243, the code generator 244, etc. included in the detection unit 240.

Since these various resistance values are reflected in the code value of the first detection signal DOUT1 or the code value of the second detection signal DOUT2, an estimated resistance value RPANEL illustrated in mathematical formula 1 may not be accurate. When the estimated resistance value RPANEL is not accurate, errors may occur in which the first crack detection target 201 is determined as a defective product even though it is a good product.

FIG. 10 is a circuit diagram of a resistance adjustment unit according to a second embodiment.

As illustrated in FIG. 10, the resistance adjustment unit 220 may comprise a plurality of resistors 220-1 to 220-k, a plurality of first switches SW11 to SW1k and a second switch SW00.

The plurality of resistors 220-1 to 220-k may be connected in parallel with each other. The plurality of first switches SW11 to SW1k may be connected in series to the plurality of resistors 220-1 to 220-k, respectively. By selective switching control of the plurality of first switches SW11 to SW1k, at least one or more resistor of the plurality of resistors 220-1 to 220-k may be selected, so that the reference resistance value may be adjusted using the resistance value of the selected at least one or more resistor.

Meanwhile, the second switch SW00 may be connected in parallel with the resistors 220-1 to 220-k. For example, the other side of the resistor 220-1 to 220-k may be connected to one side of the first switch SW11 to SW1k. In this instance, one side of the second switch SW00 may be connected to one side of the resistor 220-1 to 220-k, and the other side of the second switch SW00 may be connected to the other side of the first switch SW11 to SW1k.

The second switch SW00 may be used to obtain a third detection signal DOUT3 in which the resistance value existing in the signal supply unit 210, the path control unit 230, the detection unit 240, etc. is reflected. To this end, as illustrated in FIG. 2, the path control unit 230 may select the third path, and the resistance adjustment unit 220 may turn on the second switch SW00. Accordingly, the detection signal RMCP of the signal supply unit 210 may be provided to the detection unit 240 by passing through the second switch SW00 of the resistance adjustment unit 220.

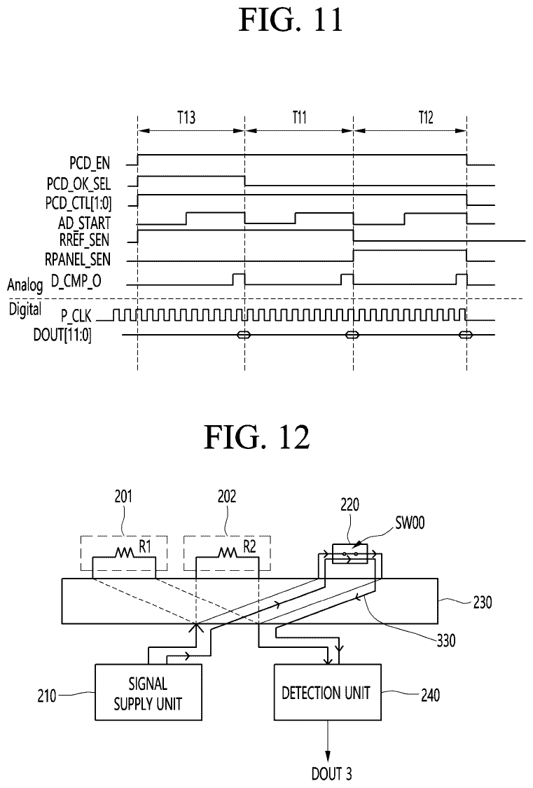

As illustrated in FIG. 11, a third section T13 may be included in one period. In FIG. 11, the third section T13 may be positioned temporally before the first section T11, but it may also be positioned between the first section T11 and the second section T12 or after the third section T13.

As illustrated in FIG. 12, the third path may be selected by the path control unit 230 during the third section T13, so that the second switch SW00 of the resistance adjustment unit 220 may be connected to the signal supply unit 210 and the detection unit 240. At this time, the second switch SW00 may be turned on. In this instance, the detection signal RMCP of the signal supply unit 210 may be provided to the detection unit 240 as the first output signal RMCN via the second switch SW00 of the resistance adjustment unit 220. The detection unit 240 may obtain the third detection signal DOUT3 based on the first output signal RMCN, but since this has been described above, a detailed description thereof will be omitted.

The third detection signal DOUT3 may be a signal that reflects the resistance value existing in the signal supply unit 210, the path control unit 230, the detection unit 240, etc.

The crack detection device 200 according to the embodiment may detect cracks in one of the plurality of crack detection targets 201 and 202, for example, the first crack detection target 201, based on the first detection signal DOUT1, the second detection signal DOUT2, and the third detection signal DOUT3.

That is, cracks in the first crack detection target 201 may be detected using mathematical formula 2. Mathematical formula 2 may be an estimated resistance value obtained by the crack detection device 200 according to the first embodiment for the first crack detection target 201, i.e., the panel 110, but estimated resistance values for other crack detection targets 201 and 202 may also be obtained using mathematical formula 2.

RPANEL=Rref·[(TPANEL[code]−Tref0k[code])/(TREF[code]−Tref0k[code])] [Mathematical Formula 2]

RPANEL is an estimated resistance value for the panel 110 obtained by the crack detection device 200 according to the embodiment, and Rref may be a reference resistance value adjusted by the resistance adjustment unit 220. TREF[code] may be a code value of a first detection signal DOUT1 obtained on a first path 310 via a resistance adjustment unit 220, and TPANEL[code] may be a code value of a second detection signal DOUT2 obtained on a second path 320 via a first crack detection target 201. Tref0k[code] may be a code value of a third detection signal DOUT3 obtained via a second switch SW00 of a resistance adjustment unit 220.

RPANEL, Rref, TREF[code], TPANEL[code], and Tref0k[code] may have binary values, but are not limited thereto.

As illustrated in mathematical formula 2, since the code value of the third detection signal DOUT3 is subtracted from the code value of the second detection signal DOUT2 and subtracted from the code value of the first detection signal DOUT1, the resistance values present in the signal supply unit 210, the path control unit 230, and the detection unit 240 may be removed from the estimated resistance value for the panel 110. Accordingly, the accuracy of the estimated resistance value for the panel 110 can be dramatically increased, and errors in crack detection can be prevented.

### Display Device According to a Second Embodiment

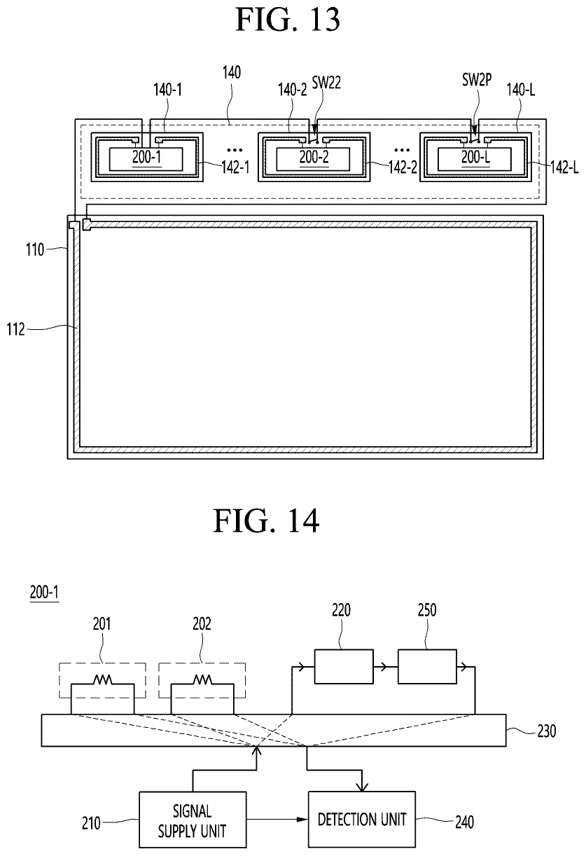

FIG. 13 is a block diagram of a display device according to the second embodiment. Drawing reference numerals omitted in FIG. 13 may be adopted in FIGS. 1 to 12.

Referring to FIG. 13, the display device according to the second embodiment may comprise a panel 110 and a data driving device 140. Although not shown, the display device according to the second embodiment may comprise a data processing device 130, a gate driving device 150, etc.

The data driving device 140 may comprise a plurality of source driving circuits 140-1 to 140-L. The source driving circuit may be configured as an integrated circuit.

The plurality of source driving circuits 140-1 to 140-L may be connected in series in an electrically set communication manner. The plurality of source driving circuits 140-1 to 140-L may be connected to the data processing device 130 in an electrically set communication manner.

One of the plurality of source driving circuits 140-1 to 140-L may be designated as a master source driving circuit, and the remaining source driving circuits may be designated as slave source driving circuits. For example, as illustrated in FIG. 13, a first source driving circuit 140-1 may be designated as a master source driving circuit, and the remaining source driving circuits 140-2 to 140-L may be designated as slave source driving circuits. Meanwhile, the slave source driving circuit may be changed to a master source driving circuit, and the master source driving circuit may be changed to a slave source driving circuit.

Hereinafter, it is assumed that the first source driving circuit 140-1 is designated as a master source driving circuit, and the remaining source driving circuits 140-2 to 140-L are designated as slave source driving circuits. Therefore, in the description below, the master source driving circuit may adopt the drawing reference numeral “140-1” of the first source driving circuit, and the slave source driving circuit may adopt the drawing reference numerals “140-2 to 140-L” of the remaining source driving circuits.

At least one of the plurality of source driving circuits 140-1 to 140-L may comprise a crack detection device 200. In this instance, the one source driving circuit may detect cracks for the plurality of crack detection targets 201 and 202 using the crack detection device 200.

The plurality of source driving circuits 140-1 to 140-L may each comprise a crack detection device 200. In this instance, the plurality of source driving circuits 140-1 to 140-L may detect cracks for the source driving circuit itself using the crack detection device 200, respectively.

Meanwhile, when detecting cracks for crack detection targets 201 and 202 located externally rather than the source driving circuit itself, some of the source driving circuits 140-1 to 140-L may detect cracks for two or more crack detection targets 201 and 202 located externally. For example, the master source driving circuit may detect cracks for two or more crack detection targets 201 and 202 located externally using the crack detection device 200.

For example, a first detection pad 112 may be provided along an edge of the panel 110. For example, second detection pads 142-1 to 142-L may be provided along edges of the plurality of source driving circuits 140-1 to 140-L. Both ends of each of the first detection pad 112 and the second detection pads 142-1 to 142-L may be connected to the path control unit 230 of the crack detection device 200.

The first detection pad 112 on the panel 110 may be connected to the crack detection device 200 via the plurality of source driving circuits 140-1 to 140-L.

For example, when a first crack detection device 200-1 of the first source driving circuit 140-1 detects cracks on the panel 110, the first detection pad 112 on the panel 110 may be connected to the path control unit 230 of the first crack detection device 200-1 of the first source driving circuit 140-1 via the second source driving circuit 140-2 to the L-th source driving circuit 140-L.

Each of the second source driving circuit 140-2 to the L-th source driving circuit 140-L may comprise connection switches SW22 to SW2P. The connection switches SW22 to SW2P of the second source driving circuit 140-2 to the L-th source driving circuit 140-L may be connected to each other. When the connection switches SW22 to SW2P of the second source driving circuit 140-2 to the L-th source driving circuit 140-L are turned on, the first detection pad 112 on the panel 110 may pass through the second source driving circuit 140-2 to the L-th source driving circuit 140-L. When the connection switches SW22 to SW2P of the second source driving circuit 140-2 to the L-th source driving circuit 140-L are turned off, the connection between the first detection pad 112 on the panel 110 and the path control unit 230 of the first crack detection device 200-1 of the first source driving circuit 140-1 may be blocked.

Although not shown, the first source driving circuit 140-1 may also comprise a connection switch. The connection switch of the first source driving circuit 140-1 may be turned off. When the crack detection device 200 of one of the second source driving circuit 140-2 to the L-th source driving circuit 140-L detects cracks on the panel 110, the connection switch of the first source driving circuit 140-1 may be turned on. At this time, the connection switch of the one source driving circuit may be turned off.

As an example, as illustrated in FIG. 2 and FIG. 3, cracks on the panel 110 may be detected as the first crack detection target 201. When the path control unit 230 selects the first path 310, the detection signal RMCP of the signal supply unit 210 may be provided as a first output signal RMCN to the detection unit 240 via the resistance adjustment unit 220 whose reference resistance value is adjusted to the resistance value R1 of the panel 110. The detection unit 240 may obtain a first detection signal DOUT1 comprising a code value corresponding to the reference resistance value adjusted by the resistance adjustment unit 220 based on the first output signal RMCN.

When the path control unit 230 selects the second path 320, the detection signal RMCP of the signal supply unit 210 may be provided as a first output signal RMCN to the detection unit 240 via the first detection pad 112 provided on the panel 110. The detection unit 240 may obtain a second detection signal DOUT2 comprising a code value corresponding to the resistance value R1 of the first detection pad on the panel 110 based on the first output signal RMCN.

While the path control unit 230 selects the second path 320, the connection switch (not shown) of the first source driving circuit 140-1 may be turned off, and the connection switches SW22 to SW2P of the second source driving circuit 140-2 to the L-th source driving circuit 140-L may be turned on.

As illustrated in FIG. 10, when the path control unit 230 selects the third path, the detection signal RMCP of the signal supply unit 210 may be provided to the detection unit 240 as the first output signal RMCN via the second switch SW00 of the resistance adjustment unit 220. The detection unit 240 may obtain the third detection signal DOUT3 comprising the code value corresponding to the resistance value existing in the signal supply unit 210, the path control unit 230, the detection unit 240, etc. based on the first output signal RMCN.

Based on the first detection signal DOUT1, the second detection signal DOUT2, and the third detection signal DOUT3, the estimated resistance value for the panel 110 may be obtained using mathematical formula 2. The estimated resistance value for the panel 110 and the actual resistance value of the first detection pad 112 on the panel 110 may be compared to detect cracks in the panel 110.

Similarly, as illustrated in FIGS. 2 and 3, cracks in the plurality of source driving circuits 140-1 to 140-L themselves may be detected as the second crack detection target 202. For example, when the path control unit 230 selects the first path 310 in a second crack detection device 200-2 of the second source driving circuit 140-2, the detection signal RMCP of the signal supply unit 210 may be provided to the detection unit 240 as a first output signal RMCN via the resistance adjustment unit 220 whose reference resistance value is adjusted to the resistance values R2 of the second detection pads 142-2 of the second source driving circuit 140-2. The detection unit 240 may obtain a first detection signal DOUTI comprising a code value corresponding to the reference resistance value adjusted by the resistance adjustment unit 220 based on the first output signal RMCN.

When the path control unit 230 selects the second path 320, the detection signal RMCP of the signal supply unit 210 may be provided to the detection unit 240 as a first output signal RMCN via the second detection pads 142-2 of the second source driving circuit 140-2. The detection unit 240 may obtain a second detection signal DOUT2 comprising a code value corresponding to the resistance value R2 of the second detection pads 142-2 of the second source driving circuit 140-2 based on the first output signal RMCN.

As illustrated in FIG. 10, when the path control unit 230 selects the third path, the detection signal RMCP of the signal supply unit 210 may be provided to the detection unit 240 as the first output signal RMCN via the second switch SW00 of the resistance adjustment unit 220. The detection unit 240 may obtain the third detection signal DOUT3 comprising the code value corresponding to the resistance value existing in the signal supply unit 210, the path control unit 230, the detection unit 240, etc. based on the first output signal RMCN.

Based on the first detection signal DOUT1, the second detection signal DOUT2, and the third detection signal DOUT3, the estimated resistance values for the second detection pads 142-2 of the second source driving circuit 140-2 may be obtained using mathematical formula 2. The estimated resistance values of the second detection pad 142-1 to 142-L of the second source driving circuit 140-2 and the actual resistance values R2 of the second detection pads 142-2 of the second source driving circuit 140-2 may be compared, so that cracks in the second source driving circuit 140-2 may be detected.

Meanwhile, as described above, the plurality of source driving circuits 140-1 to 140-L may comprise a plurality of connection switches SW22 to SW2P. The plurality of connection switches SW22 to SW2P may have internal resistance values.

When the first path 310, the second path 320, and the third path are selected to detect cracks in the panel 110, the plurality of connection switches SW22 to SW2P may be turned on, and the first detection signal DOUT1, the second detection signal DOUT2, and the third detection signal DOUT3 may be obtained via each of the plurality of connection switches SW22 to SW2P. In this instance, the first detection signal DOUT1, the second detection signal DOUT2, and the third detection signal DOUT3 may reflect the internal resistance values of the plurality of connection switches SW22 to SW2P, respectively, so that the accuracy of the estimated resistance value for the panel 110 represented by mathematical formula 2 can be reduced.

Referring to FIGS. 14 to 17 below, a method for increasing the accuracy of the estimated resistance value for the panel 110 by offsetting the internal resistance values of each of the plurality of connection switches SW22 to SW2P is described.

FIG. 14 illustrates a crack detection device according to the second embodiment. FIG. 15 is a circuit diagram of the first resistance adjustment unit and the second resistance adjustment unit of FIG. 14.

Referring to FIGS. 14 and 15, the crack detection device 200 according to the second embodiment may comprise a signal supply unit 210, a resistance adjustment unit, a path control unit 230, and a detection unit 240. Since the signal supply unit 210, the path control unit 230, and the detection unit 240 have been described above, a detailed description thereof will be omitted.

The resistance adjustment unit may comprise a first resistance adjustment unit 220 and a second resistance adjustment unit 250. The first resistance adjustment unit 220 has been described above, so that a detailed description thereof will be omitted.

In FIG. 15, the second switch (SW00 of FIG. 10) is omitted from the first resistance adjustment unit 220, but the second switch SW00 may be included.

The second resistance adjustment unit 250 may be connected in series with the first resistance adjustment unit 220.

The second resistance adjustment unit 250 may comprise a plurality of third switches SW31 to SW3Q connected in series with each other. The second resistance adjustment unit 250 may comprise a plurality of fourth switches SW41 to SW4Q connected in parallel with the plurality of third switches SW31 to SW3Q.

The detection signal RMCP of the signal supply unit 210 may pass through the third switches SW31 to SW3Q when the third switches SW31 to SW3Q are turned on. The fourth switches SW41 to SW4Q may be a bypass switch. That is, the fourth switches SW41 to SW4Q may prevent the detection signal RMCP from passing through the third switches SW31 to SW3Q.

For example, the third switches SW31 to SW3Q and the fourth switches SW41 to SW4Q may be switched complementarily. When the third switches SW31 to SW3Q are turned on, the fourth switches SW41 to SW4Q may be turned off.

The number of third switches to be turned on among the plurality of third switches SW31 to SW3Q may be determined in consideration of the number of the plurality of slave source driving circuits. For example, when the internal resistance value of the plurality of third switches SW31 to SW3Q is the same as the internal resistance value of the connection switches SW22 to SW2P of the plurality of slave source driving circuits, respectively, the number of third switches to be turned on among the plurality of third switches SW31 to SW3Q may be the same as the number of connection switches SW22 to SW2P. That is, when the number of connection switches SW22 to SW2P is 2, the number of third switches to be turned on among the plurality of third switches SW31 to SW3Q may also be 2. In this instance, among the plurality of fourth switches SW41 to SW4Q, the fourth switches of two connected in parallel with the turned-on third switches may be turned off, and the remaining fourth switches may be turned on.

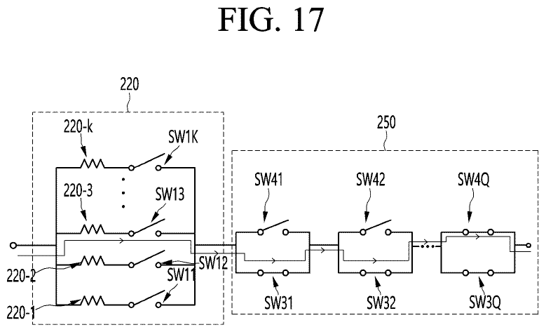

For example, the first path 310 may be selected by the path control unit 230 to detect cracks in the panel 110. In this instance, the detection signal RMCP of the signal supply unit 210 may be provided to the detection unit 240 as the first output signal RMCN via the first resistance adjustment unit 220 and the second resistance adjustment unit 250. At this time, the first resistance adjustment unit 220 may adjust the reference resistance value to the resistance value R1 of the panel 110. The second resistance adjustment unit 250 may select the third switches SW31 to SW3Q as many as the number of slave source driving circuits. For example, as illustrated in FIG. 17, the detection signal RMCP may be provided to the detection unit 240 as a first output signal RMCN via the resistor 220-3 having the adjusted reference resistance value and the third switches SW31 and SW32 of two. Accordingly, the internal resistance values as many as the number of the selected third switches SW31 and SW32 may be reflected in the first detection signal DOUT1 obtained from the first output signal RMCN by the detection unit 240. Meanwhile, the internal resistance value of each of the fourth switches SW41 to SW4Q may be 0 or close to 0.

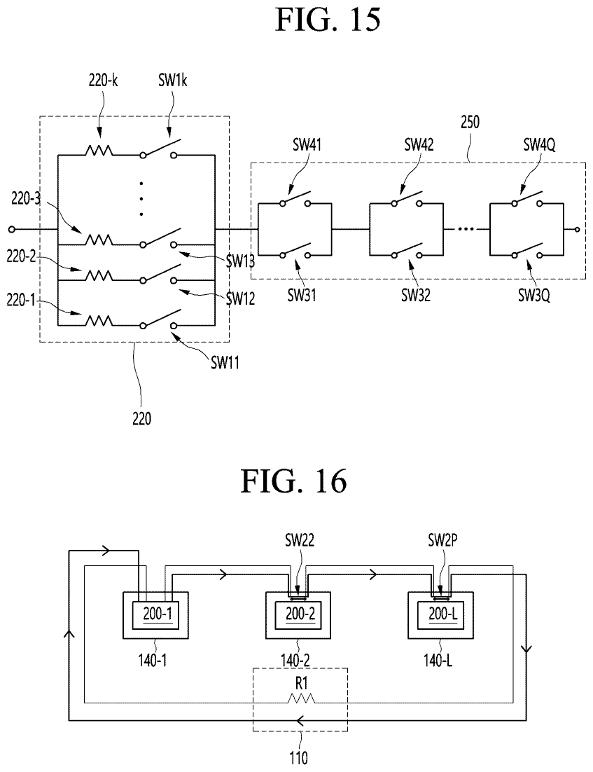

Thereafter, as illustrated in FIG. 16, when the second path 320 is selected by the path control unit 230, the detection signal RMCP of the signal supply unit 210 may be provided to the detection unit 240 as a first output signal RMCN via the panel 110 and the plurality of slave source driving circuits. In this instance, the internal resistance values of the connection switches of the plurality of slave source driving circuits may be reflected in the second detection signal DOUT2 obtained from the first output signal RMCN by the detection unit 240.

When the estimated resistance value for the panel 110 is obtained using mathematical formula 1 or mathematical formula 2, the internal resistance values of the connection switches of the plurality of slave source driving circuits may be offset by the internal resistance values of the number of the selected third switches SW31 to SW3Q reflected in the first detection signal DOUT1. Accordingly, the accuracy of the estimated resistance value for the panel 110 can be increased by the internal resistance values of the switches for connection of the plurality of slave source driving circuits, so that errors in crack detection can be prevented.

The above detailed description should not be construed as limiting in all respects and should be considered illustrative. The scope of the embodiment should be determined by reasonable interpretation of the appended claims, and all changes within the equivalent range of the embodiment are included in the scope of the embodiment.

1. A crack detection device, comprising:
a signal supply unit configured to supply a detection signal;
a resistance adjustment unit configured to adjust a reference resistance value to correspond to resistance values of a plurality of crack detection targets using a plurality of resistors;
a path control unit configured to select a first path and a second path, and in which the detection signal passes through at least one resistor through the first path and passes through one of the plurality of crack detection targets through the second path; and
a detection unit configured to detect cracks in the one crack detection target based on a first detection signal obtained from an output signal on the first path and a second detection signal obtained from an output signal on the second path,
wherein when the first path is selected, the at least one resistor is connected to the signal supply unit, and when the second path is selected, the crack detection target is connected to the signal supply unit.

2. The crack detection device of claim 1, wherein one period comprises a first section and a second section,
wherein the detection unit is configured:
to obtain the first detection signal during the first section, and
to obtain the second detection signal during the second section.

3. The crack detection device of claim 1, wherein the plurality of resistors are connected in parallel with each other, and
wherein the resistance adjustment unit comprises a plurality of first switches configured to be connected in series to the plurality of resistors, respectively.

4. The crack detection device of claim 3, wherein the resistance adjustment unit is configured:
to adjust the reference resistance value to correspond to a resistance value of the one crack detection target by switching the plurality of first switches.

5. The crack detection device of claim 1, wherein the resistance adjustment unit comprises a second switch connected in parallel with the resistor.

6. The crack detection device of claim 5, wherein the path control unit is configured to select a third path through which the detection signal passes through the second switch,
wherein the detection unit is configured to detect cracks in the one crack detection target based on the first detection signal, the second detection signal, and a third detection signal, and
wherein the third detection signal is configured to be obtained on the selected third path.

7. The crack detection device of claim 6, wherein the one period comprises a third section, and
wherein the detection unit is configured to obtain the third detection signal during the third section.

8. A crack detection method, comprising:
supplying, by a signal supply unit, a detection signal;
adjusting, by a resistance adjustment unit, a reference resistance value to correspond to resistance values of a plurality of crack detection targets using a plurality of resistors;
selecting, by a path control unit, a first path and a second path—wherein the detection signal passes through at least one resistor through the first path and passes through one crack detection target among the plurality of crack detection targets through the second path; and
detecting, by a detection unit, cracks in the one crack detection target based on a first detection signal obtained from an output signal on the first path and a second detection signal obtained from an output signal on the second path,
wherein when the first path is selected, the at least one resistor is configured to be connected to the signal supply unit, and when the second path is selected, the crack detection target is configured to be connected to the signal supply unit.

9. The crack detection method of claim 8, comprising:
selecting a third path through which the detection signal passes through a second switch connected in parallel with the resistor,
wherein the detecting of cracks comprises:
detecting cracks in the one crack detection target based on the first detection signal, the second detection signal, and a third detection signal, and
wherein the third detection signal is configured to be obtained on the selected third path.

10. A data driving device configured to supply a data signal to a panel, comprising:
a plurality of source driving circuits, each of which comprises a crack detection device,
wherein the crack detection device comprises:
a signal supply unit configured to supply a detection signal;
a first resistance adjustment unit configured to adjust a reference resistance value to correspond to resistance values of a plurality of crack detection targets using a plurality of first resistors;
a path control unit configured to select a first path and a second path, and in which the detection signal passes through at least one resistor through the first path and passes through one of the plurality of crack detection targets through the second path; and
a detection unit configured to detect cracks in the one crack detection target based on a first detection signal obtained from an output signal on the first path and a second detection signal obtained from an output signal on the second path,
wherein when the first path is selected, the at least one resistor is connected to the signal supply unit, and when the second path is selected, the crack detection target is connected to the signal supply unit.

11. The data driving device of claim 10, wherein one of the plurality of source driving circuits is designated as a master source driving circuit, and the remaining source driving circuits are designated as slave source driving circuits, and
wherein in the master source driving circuit, the detection unit is configured to obtain the second detection signal from the panel as the one crack detection target by passing the detection signal through the panel and the plurality of slave source driving circuits.

12. The data driving device of claim 11, wherein in the master source driving circuit, the crack detection device comprises:
a second resistance adjustment unit configured to offset resistance values of the plurality of slave source driving circuits using a plurality of second resistors.

13. The data driving device of claim 10, wherein one of the plurality of source driving circuits is designated as a master source driving circuit, and the remaining source driving circuits are designated as slave source driving circuits, and
wherein in the master source driving circuit, the detection unit is configured to obtain the second detection signal from the master source driving circuit as the one crack detection target by passing detection signal through the master source driving circuit.

14. The data driving device of claim 10, wherein one of the plurality of source driving circuits is designated as a master source driving circuit, and the remaining source driving circuits are designated as slave source driving circuits, and
wherein in one of the designated plurality of slave source driving circuits, the detection unit is configured to obtain the second detection signal from the one slave source driving circuit as the one crack detection target by passing the detection unit through the one slave source driving circuit.
